(19) United States
(12) Patent Application Publication
(10) Pub. No.: US 2025/0029936 A1
(43) Pub. Date: Jan. 23, 2025

(54) SEMICONDUCTOR PACKAGE

(71) Applicant: Samsung Electronics Co., Ltd., Suwon-si (KR)

(72) Inventor: Jongwon Lee, Suwon-si (KR)

(21) Appl. No.: 18/672,372

(22) Filed: May 23, 2024

(30) Foreign Application Priority Data
Jul. 17, 2023 (KR) 10-2023-0092238

(51) Int. Cl. H01L 23/00; H01L 23/31; H01L 23/498; H01L 25/065; H10B 80/00

(52) U.S. Cl. CPC H01L 23/562; H01L 23/3157; H01L 23/49811; H01L 25/0657; H10B 80/00; H01L 24/16; H01L 24/32; H01L 24/73; H01L 2224/16227; H01L 2224/32225; H01L 2224/73204; H01L 2225/06562

(57) ABSTRACT

A semiconductor package includes a substrate that includes a first surface and a second surface that is opposite to the first surface, where the first surface includes a first region and a second region, where the substrate includes a wiring circuit layer; first connection pads in the first region of the substrate and second connection pads in the second region of the substrate, a semiconductor chip structure that is on the first region of the substrate and is connected to the first connection pads by conductive bumps, a stiffener that extends along the first side and is in the first region of the substrate, an underfill on the first region of the substrate, where the underfill is spaced apart from the stiffener, and external connection conductors that are on the second surface of the substrate and electrically connected to the wiring circuit layer.

### CROSS-REFERENCE TO RELATED APPLICATION(S)

This application claims benefit of priority to Korean Patent Application No. 10-2023-0092238 filed on Jul. 17, 2023 in the Korean Intellectual Property Office, the disclosure of which is incorporated herein by reference in its entirety.

### TECHNICAL FIELD

The present disclosure relates to a semiconductor package.

### BACKGROUND

For next-generation high-performance communication devices, semiconductor packages with logic and memory elements having a high bandwidth memory (HBM) are attracting attention. A semiconductor package may include a logic chip mounted on a substrate and a plurality of memory stacks. In particular, a semiconductor package designed to be suitable for mobile communication may be manufactured with a thin thickness, and may thus be very vulnerable to external physical stress, such as warpage or the like. In particular, warpage may occur in extension directions of boundary regions (or boundaries) of chips, which may cause physical or electrical damage to the semiconductor package.

### SUMMARY

An aspect of the present disclosure is to provide a semiconductor package having improved reliability.

According to an aspect of the present disclosure, a semiconductor package includes a substrate that includes a first surface and a second surface that is opposite to the first surface, where the first surface includes a first region and a second region, where the first region is adjacent to a first side of the substrate, where the second region is adjacent to a second side of the substrate, where the first side and the second side are opposite to each other, and where the substrate includes a wiring circuit layer; first connection pads in the first region of the substrate and second connection pads in the second region of the substrate, where the first connection pads and the second connection pads are electrically connected to the wiring circuit layer; a semiconductor chip structure that is on the first region of the substrate and is connected to the first connection pads by conductive bumps; a stiffener that extends along the first side and is in the first region of the substrate, where the stiffener extends to both corners of the first side; an underfill on the first region of the substrate, where the underfill is spaced apart from the stiffener, where the underfill at least partially surrounds the conductive bumps, and where the underfill is between the semiconductor chip structure and the substrate; and external connection conductors that are on the second surface of the substrate and electrically connected to the wiring circuit layer.

According to an aspect of the present disclosure, a semiconductor package includes a substrate; a semiconductor chip structure that is on the substrate and adjacent to one side surface of the substrate; a stiffener that overlaps at least two corner portions of an upper surface of the substrate in a first direction, where the stiffener is spaced apart from the semiconductor chip structure, and where the stiffener includes a tetragonal shape that at least partially surrounds the semiconductor chip structure; and an underfill that overlaps at least a portion of a lower end of the semiconductor chip structure in the first direction.

According to an aspect of the present disclosure, a semiconductor package includes a substrate; a first semiconductor chip structure and a second semiconductor chip structure that are on an upper surface of the substrate and include different sizes; a stiffener that is spaced apart from the first semiconductor chip structure and the second semiconductor chip structure and is on the upper surface of the substrate, where the stiffener extends along a perimeter of the first semiconductor chip structure and a perimeter of the second semiconductor chip structure; and an underfill that seals at least a portion of the first semiconductor chip structure and at least a portion of the second semiconductor chip structure, where the first semiconductor chip structure and the second semiconductor chip structure include a plurality of semiconductor chips that extend in a direction that is perpendicular to the upper surface of the substrate.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a top view illustrating an upper surface of a substrate of a semiconductor package according to an embodiment, and FIG. 1B is a cross-sectional view of the semiconductor package illustrated in FIG. 1A, taken along line I-I′.

FIG. 2 is a top view illustrating an upper surface of a substrate of a semiconductor package according to an embodiment.

FIG. 3A is a top view illustrating an upper surface of a substrate of a semiconductor package according to an embodiment, and FIG. 3B is a cross-sectional view of the semiconductor package illustrated in FIG. 3A, taken along line II-II′.

FIG. 4A is a top view illustrating an upper surface of a substrate of a semiconductor package according to an embodiment, and FIG. 4B is a cross-sectional view of the semiconductor package illustrated in FIG. 4A, taken along line III-III′.

FIG. 5 is a top view illustrating an upper surface of a substrate of a semiconductor package according to an embodiment.

FIG. 6A is a top view illustrating an upper surface of a substrate of a semiconductor package according to an embodiment, and FIG. 6B is a cross-sectional view of the semiconductor package illustrated in FIG. 6A, taken along line IV-IV′.

FIGS. 7A, 8A, and 9A are top views of each main process illustrating a method for manufacturing a semiconductor package according to an embodiment, and FIGS. 7B, 8B, and 9B are cross-sectional views of the top views of FIGS. 7A, 8A and 9A, taken along line I-I′, respectively.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection.

Hereinafter, preferred embodiments will be described with reference to the attached drawings.

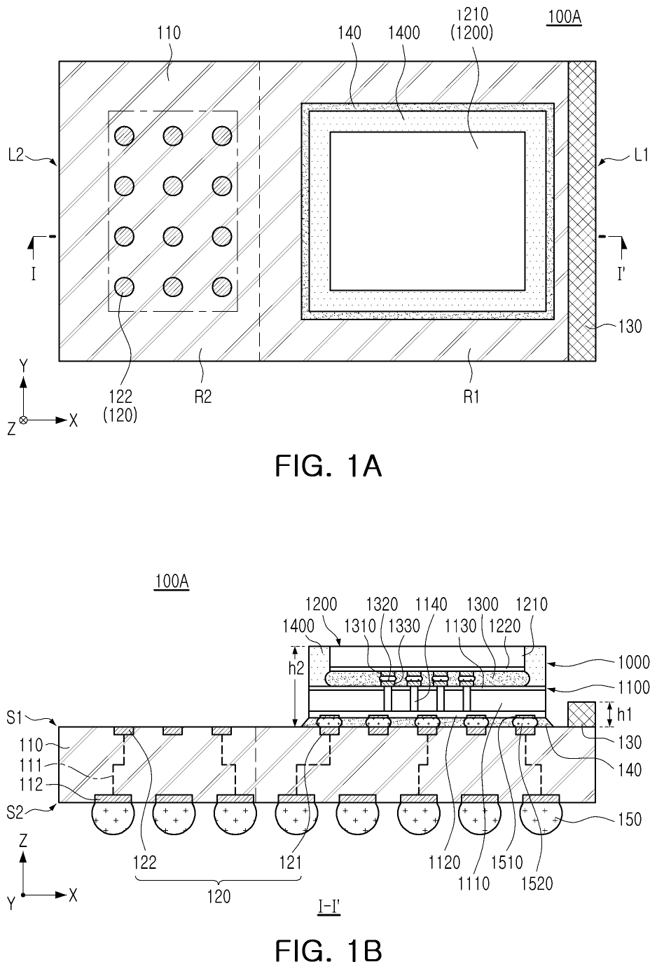

FIG. 1A is a top view illustrating an upper surface of a substrate 110 of a semiconductor package 100A according to an embodiment, while FIG. 1B is a cross-sectional view of the semiconductor package 100A illustrated in FIG. 1A, taken along line I-I′.

Referring to FIGS. 1A and 1B, a semiconductor package 100A according to an embodiment may include a substrate 110, a semiconductor chip structure 1000, a stiffener 130, and an underfill 140. Additionally, the semiconductor package 100A may further include first and second connection pads 121 and 122 and external connection conductors 150.

The present disclosure may introduce a stiffener formed of a material with a low coefficient of thermal expansion into one side corner portion of a substrate to which a semiconductor chip structure is asymmetrically attached, thereby inhibiting warpage that may occur when high temperature heat is applied in a reflow process, and thereby improving the reliability of a semiconductor package. Hereinafter, each component of the semiconductor package 100A will be described in detail with reference to the drawings.

The substrate 110 may be a support substrate on which the semiconductor chip structure 1000 is mounted, and may include lower pads 112 disposed on a lower surface of a body, upper pads 120 disposed on an upper surface of the body, and an interconnection circuit layer 111 electrically connecting the lower pads 112 and the upper pads 120. The interconnection circuit layer 111 may form an electrical path connecting a lower surface and an upper surface of the substrate 110. The substrate 110 may be a semiconductor package substrate including a printed circuit board (PCB), a ceramic substrate, a glass substrate, a tape wiring substrate, or the like. The body of the substrate 110 may include different materials depending on a type of substrate. For example, when the package substrate 110 is a printed circuit board, the body may be a copper clad laminate, or a structure in which a wiring layer is additionally stacked on one or both surfaces of the copper clad laminate. A solder resist layer may be formed on the lower and upper surfaces of the substrate 110, respectively.

The substrate 110 may have a first surface S1 and a second surface S2 located opposite to the first surface S1. The first surface S1 and the second surface S2 may refer to the upper and lower surfaces of the substrate 110, respectively.

The first surface S1 of the substrate 110 may have a tetragonal shape in plan view, and may have a first side L1 and a second side L2 opposite the first side L1. The first surface S1 of the substrate 110 may have a first region R1 adjacent to the first side L1 and a second region R2 adjacent to the second side L2. The first region R1 and the second region R2 may be regions arranged side by side in a first direction (e.g., X-axis direction). The first region R1 and the second region R2 may have different areas, and the first region R1 may be greater than the second region R2.

The interconnection circuit layer 111 may include, for example, a ground pattern, a power pattern, and a signal pattern. The signal pattern may provide a path through which various signals, such as a data signal or the like, are transmitted/received.

The lower pads 112 may include, for example, a metal material including copper (Cu), aluminum (Al), silver (Ag), tin (Sn), gold (Au), nickel (Ni), lead (Pb), titanium (Ti), or an alloy thereof. The lower pads 112 may include landing pads on which the external connection conductors 150 are mounted.

The upper pads 120 may include first connection pads 121 disposed in the first region R1 of the substrate 110, and second connection pads 122 disposed in the second region R2 of the substrate 110. The upper pads 120 may include, for example, a metal material including copper (Cu), aluminum (Al), silver (Ag), tin (Sn), gold (Au), nickel (Ni), lead (Pb), titanium (Ti), or an alloy thereof. The upper pads 120 may include landing pads on which the semiconductor chip structure 1000 is mounted.

The first connection pads 121 may be disposed in the first region R1 of the substrate 110, and may be electrically connected to the interconnection circuit layer 111. A plurality of first connection pads 121 may be disposed in the first region R1. The first connection pads 121 may be electrically connected to the semiconductor chip structure 1000 through conductive bumps 1520.

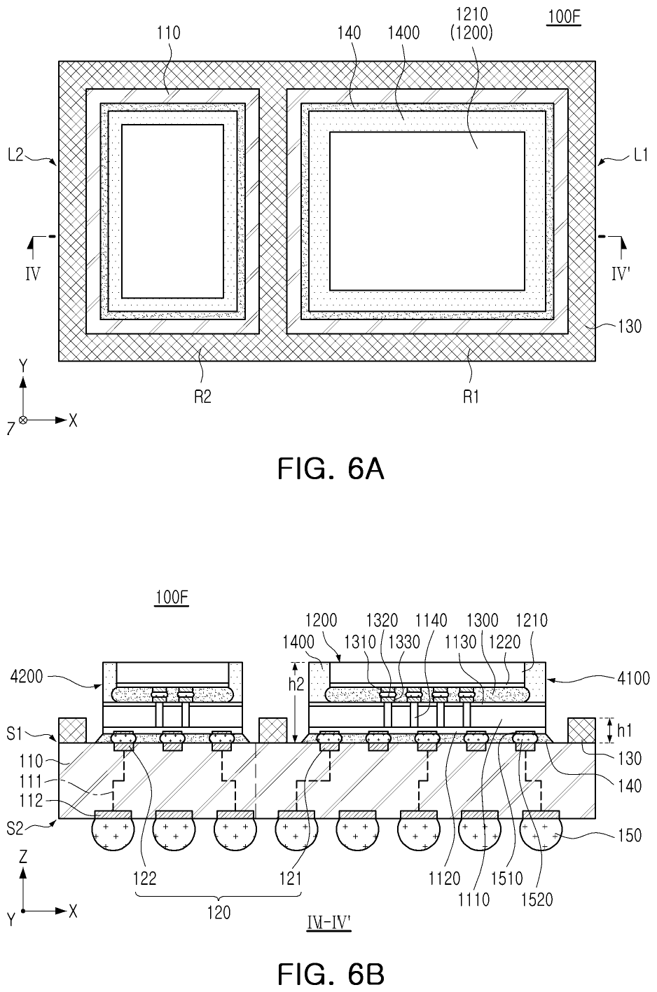

The second connection pads 122 may be disposed in the second region R2 of the substrate 110, and may be electrically connected to the interconnection circuit layer 111. A plurality of second connection pads 122 may be disposed in the second region R2. In an embodiment to be described later, the second connection pads 122 may be spaced apart from a first semiconductor chip structure 4100 through second conductive bumps, and may be electrically connected to a second semiconductor chip structure 4200 disposed in the second region R2 (see FIGS. 6A and 6B). In another embodiment, a memory chip structure (not illustrated) including a memory chip may be included on the second connection pads 122. A region illustrated with a dashed-dotted line in FIG. 1A may be expressed for convenience to distinguish a region on which the second semiconductor chip structure 4200 or the memory chip structure is mounted.

The semiconductor chip structure 1000, which may also be referred to as a first package 1000, may be disposed in the first region R1 of the substrate 110. The first package 1000 may include a plurality of semiconductor chips 1100 and 1200 stacked in a vertical direction (e.g., Z-axis direction), bump structures 1320 electrically connecting the plurality of semiconductor chips 1100 and 1200, and an adhesive film 1300 fixing and supporting the plurality of semiconductor chips 1100 and 1200. For example, the semiconductor chip structure 1000 may include a first semiconductor chip 1100 and a second semiconductor chip 1200 stacked on the first semiconductor chip 1100, but the number of stacked semiconductor chips is not limited thereto.

The plurality of semiconductor chips 1100 and 1200 may include, but are not limited to, a logic chip such as an analog-to-digital converter, an application-specific IC (ASIC), or the like, and may be a memory chip including a volatile memory, such as a dynamic RAM (DRAM), a static RAM (SRAM), or the like, and a non-volatile memory, such as a phase change RAM (PRAM), a magnetic RAM (MRAM), a resistive RAM (RRAM), a flash memory, or the like.

The first semiconductor chip 1100 may include a first substrate 1110, a first circuit layer 1120, through-electrodes 1140, and a plurality of connection pads 1330 and 1510. The second semiconductor chip 1200 may be disposed on an upper surface of the first semiconductor chip 1100, and the plurality of connection bumps 1520 may be disposed on a lower surface of the first semiconductor chip 1100.

The first substrate 1110 may include, for example, a semiconductor element such as silicon or germanium (Ge), or may include a compound semiconductor such as silicon carbide (SiC), gallium arsenide (GaAs), indium arsenide (InAs), or indium phosphide (InP). The first circuit layer 1120 may be disposed on a lower surface of the first substrate 1110, which may be an active surface of the first substrate 1110, and a first insulating layer 1130 may be disposed on an upper surface of the first substrate 1110, which may be a non-active surface of the first substrate 1110.

The first circuit layer 1120 may be disposed on the lower surface of the first substrate 1110, which may be the active surface of the first substrate 1110, and may include an interlayer insulating layer (not illustrated) and a wiring structure (not illustrated). The interlayer insulating layer may include flowable oxide (FOX), tonen silazene (TOSZ), undoped silica glass (USG), borosilica glass (BSG), phosphosilica glass (PSG), borophosphosilica glass (BPSG), plasma toughened tetraethyl orthosilicate (PETEOS), fluorosilicate glass (FSG), high density plasma (HDP) oxide, plasma enhanced oxide (PEOX), flowable CVD (FCVD) oxide, or any combination thereof. At least a portion of the interlayer insulating layer surrounding the wiring structure may be formed of a low dielectric layer. The interlayer insulating layer may be formed using a chemical vapor deposition (CVD) process, a flowable CVD process, or a spin coating process.

The first insulating layer 1130 may be disposed on the upper surface of the first substrate 1110. The first insulating layer 1130 may be formed to surround upper portions of the through-electrodes 1140. The first insulating layer 1130 may electrically insulate first connection pads 1330 from a semiconductor material forming the first substrate 1110. The first insulating layer 1130 may include silicon oxide, silicon oxynitride, silicon nitride, polymer, or a combination thereof. The first insulating layer 1130 may be formed using a chemical vapor deposition (CVD) process, a flowable CVD process, or a spin coating process.

The through-electrodes 1140 may extend into the first substrate 1110, and may electrically connect at least a portion of lower mounting pads 1510 and at least a portion of first connection pads 1330. The through-electrodes 1140 may include a via plug (not illustrated) and a side barrier film (not illustrated) at least partially surrounding a side surface of the via plug. The via plug may include, for example, tungsten (W), titanium (Ti), aluminum (Al), or copper (Cu), and may be formed by a plating process, PVD process, or CVD process. The side barrier film may include titanium (Ti), titanium nitride (TiN), tantalum (Ta), or tantalum nitride (TaN), and may be formed by a plating process, a PVD process, or a CVD process. Between the side barrier film and the first substrate 1110, a side insulating layer (not illustrated) comprising an insulating material, such as silicon oxide, silicon nitride, or silicon oxynitride (e.g., high aspect ratio process (HARP) oxide), may be formed.

The plurality of connection pads 1510 and 1330 may include lower mounting pads 1510 disposed on the lower surface of the first semiconductor chip 1100, and first connection pads 1330 disposed on the upper surface of the first semiconductor chip 1100. The lower mounting pads 1510 and the first connection pads 1330 may include, for example, at least one of aluminum (Al), copper (Cu), nickel (Ni), tungsten (W), platinum (Pt), or gold (Au). The first connection pads 1330 may be connected to an integrated circuit or individual devices (not illustrated) in the first circuit layer 1120 through the through-electrodes 1140, or may be connected to the lower mounting pads 1510. The lower mounting pads 1510 and the first connection pads 1330 may include a signal pad, a power pad, and a ground pad.

The conductive bumps 1520 may be disposed below the lower mounting pads 1510, and may be electrically connected to the first semiconductor chip 1100 and the second semiconductor chip 1200. Depending on an embodiment, a plurality of conductive bumps 1520 may have a structure in which a metal pillar and a solder ball are combined. The plurality of conductive bumps 1520 may be connected to the first connection pads 121 of the substrate 110.

The second semiconductor chip 1200 may include a second substrate 1210, a second circuit layer 1220, and second connection pads 1310. Since the second circuit layer 1220 and the second substrate 1210 have the same or similar characteristics as the first circuit layer 1120 and the first substrate 1110 of the above-described first semiconductor chip 1100, detailed descriptions of the circuit layer 1220 and the second substrate 1210 may correspond to descriptions of the first circuit layer 1120 and the first substrate 1110, respectively.

The second connection pads 1310 may be disposed below the second circuit layer 1220. The second connection pads 1310 may include, for example, at least one of aluminum (Al), copper (Cu), nickel (Ni), tungsten (W), platinum (Pt), or gold (Au). The second connection pads 1310 may include a signal pad, a power pad, and a ground pad. The second connection pads 1310 may be arranged to face the first connection pads 1330, respectively. The second connection pads 1310 may be electrically connected to the first connection pads 1330 through the bump structures 1320.

The bump structures 1320 may be disposed between the first semiconductor chip 1100 and the second semiconductor chip 1200, and may electrically connect the first connection pads 1330 and the second connection pads 1310 that face each other. The bump structures 1320 may include a pillar portion (not illustrated) disposed below the second connection pads 1310, and a solder portion (not illustrated) disposed below the pillar portion and in contact with the first connection pads 1330. The pillar portion may have a cylindrical shape or a polygonal pillar shape, and may include, for example, at least one of aluminum (Al), copper (Cu), nickel (Ni), tungsten (W), platinum (Pt), or gold (Au). The solder portion may include, for example, tin (Sn) or an alloy containing tin (Sn) (e.g., Sn—Ag—Cu).

The adhesive film 1300 may be disposed between the first semiconductor chip 1100 and the second semiconductor chip 1200. The adhesive film 1300 may fill a space between the first semiconductor chip 1100 and the second semiconductor chip 1200, and may surround at least a portion of each of the first connection pads 1330 and the bump structures 1320. The adhesive film 1300 may be in contact with side surfaces of the bump structures 1320. The adhesive film 1300 may be a non-conductive film (NCF), but is not limited thereto, and may include, for example, all types of polymer films configured to perform a heat compression process.

The first package 1000 may further include an encapsulant 1400 sealing the first and second semiconductor chips 1100 and 1200. The encapsulant 1400 may cover or overlap at least a portion of the adhesive film 1300. For example, the encapsulant 1400 may be formed of an insulating material, such as an epoxy mold compound (EMC), but is not limited thereto. Depending on an embodiment, the encapsulant 1400 may be formed to expose an upper surface of the second semiconductor chip 1200.

The stiffener 130 may be disposed in the first region R1 of the substrate 110 along the first side L1. A length of the stiffener 130 in a Y-axis direction may be equal to a length of the first side L1. The stiffener 130 may extend to both corners of the first side L1. The stiffener 130 may be disposed on the upper surface of the substrate 110 to cover or overlap both corners of the first side L1.

The stiffener 130 may have a rectangular bar shape, but is not limited thereto. In an embodiment, the stiffener 130 may have a groove portion recessed in a direction of the first side L1 on an internal side surface facing the semiconductor chip structure 1000, or may have a protrusion portion extending in a direction of the second side L2 opposite to the first side L1. A height h1 of the stiffener 130 may be less than a height h2 at which the semiconductor chip structure 1000 is mounted. Specifically, a vertical distance h1 from the first surface S1 of the substrate 110 to an uppermost end of the stiffener 130 may be less than a vertical distance h2 from the first surface S1 of the substrate 110 to an uppermost end of the semiconductor chip structure 1000. A width of the stiffener 130 in an X-axis direction may be constant in a portion extending along the first side L1, but is not limited thereto.

The stiffener 130 may include a metal material having a low coefficient of thermal expansion. For example, in an embodiment, the stiffener 130 may include at least one of copper (Cu), a copper (Cu) alloy, nickel (Ni), or a nickel (Ni) alloy. In another embodiment, the stiffener 130 may include iron (Fe), particularly stainless steel such as SUS-designated stainless steel.

The stiffener 130 may serve as a reinforcing material by covering or overlapping at least one corner of the substrate 110 having an asymmetric structure. Additionally, by introducing the stiffener 130 formed of a material having a low thermal expansion coefficient, warpage of a package that may occur in a high temperature reflow process may be improved. In various embodiments, a degree of warpage of the package may be adjusted by changing a shape of the stiffener 130.

The underfill 140 may be disposed between the substrate 110 and the semiconductor chip structure 1000 to at least partially surround the conductive bumps 1520 disposed on a lower end of the semiconductor chip structure 1000. The underfill 140 may be disposed to be spaced apart from an internal side surface of the stiffener 130, e.g., a surface of the stiffener 130 closest to the semiconductor chip structure 1000. The underfill 140 may fix the conductive bumps 1520 on the substrate 110, and may physically and electrically protect the conductive bumps 1520. The underfill 140 may have a shape of which a width increases from the semiconductor chip structure 1000 toward the first surface S1 of the substrate 110. The underfill 140 may include a known insulating resin, such as epoxy resin. The underfill 140 may have a capillary underfill (CUF) structure, but is not limited thereto.

The external connection conductors 150 may be disposed on the second surface S2 of the substrate 110. The external connection conductors 150 may be electrically connected to the interconnection circuit layer 111 and the lower pads 112. The external connection conductors 150 may be formed of a conductive material having a shape such as a ball, a pin, or the like. The external connection conductors 150 may be, for example, solder balls. The external connection conductors 150 may electrically connect the semiconductor package 100A to an external device (e.g., a motherboard). A portion of the external connection conductors 150 may be electrically connected to the semiconductor chip structure 1000 through the first connection pads 121.

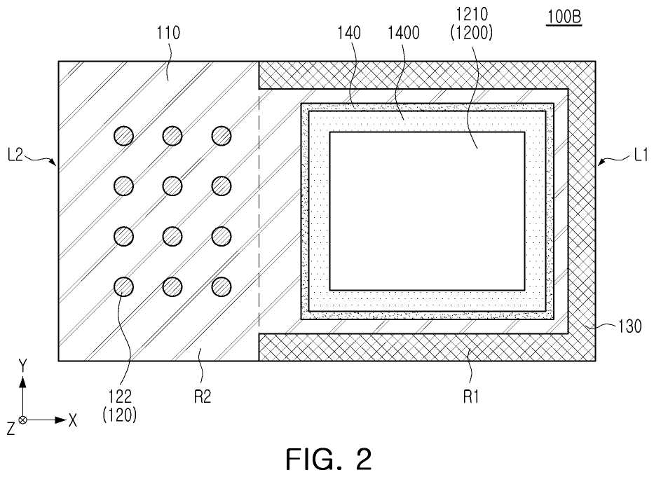

FIG. 2 is a top view illustrating an upper surface S1 of a substrate 110 of a semiconductor package 100B according to an embodiment.

Referring to FIG. 2, a semiconductor package 100B according to an embodiment may have the same or similar characteristics as illustrated in FIGS. 1A and 1B, except that a stiffener 130 may further include a portion extending in a direction that is perpendicular to a first side L1.

A semiconductor package 100B according to an embodiment may include a stiffener 130 in which several bars are connected to each other. The stiffener 130 may have a portion disposed along a first side L1 on a first surface S1 of a substrate 110, and portions extending in a direction that is perpendicular to the first side L1 (e.g., X-axis direction). The portions extending in a direction that is perpendicular to the first side L1 may be portions extending from both corners of the first side L1, and the stiffener 130 in a first region R1 may be arranged to cover or overlap both corners of the first side L1. The stiffener 130 may have a shape surrounding a semiconductor chip structure 1000 in plan view, excluding a portion adjacent to the second region R2.

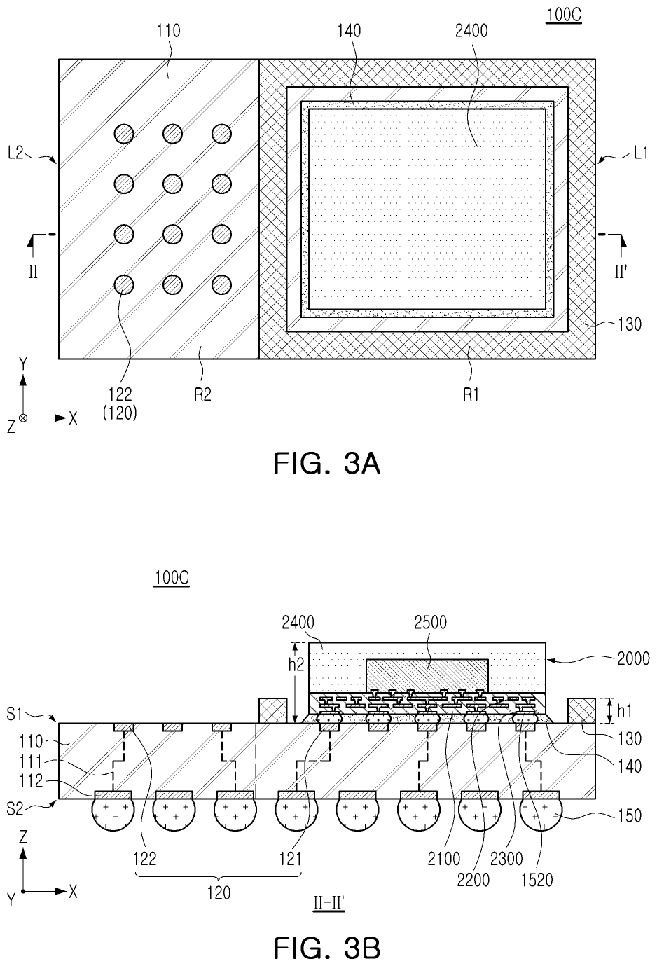

FIG. 3A is a top view illustrating an upper surface S1 of a substrate 110 of a semiconductor package 100C according to an embodiment, and FIG. 3B is a cross-sectional view of the semiconductor package 100C illustrated in FIG. 3A, taken along line II-II′.

Referring to FIGS. 3A and 3B, a semiconductor package 100C according to an embodiment may have the same or similar characteristics as illustrated with reference to FIGS. 1A, 1B, and 2 except that the semiconductor package 100C includes a semiconductor chip structure 2000, which may also be referred to as a second package 2000, and a stiffener 130 disposed to at least partially surround the second package 2000.

A semiconductor package 100C according to an embodiment may include a second package 2000 mounted in a first region R1. The second package 2000 may include a redistribution substrate 2100 including redistribution layers 2200, a semiconductor chip 2500 electrically connected to the redistribution layer 2200, and an encapsulant 2400 sealing the semiconductor chip 2500 on the redistribution substrate 2100.

The redistribution layers 2200 may further include redistribution vias for electrical connection to adjacent redistribution layers 2200. The redistribution layers 2200 may include, for example, a metal material including copper (Cu), aluminum (Al), silver (Ag), tin (Sn), gold (Au), nickel (Ni), lead (Pb), titanium (Ti), or an alloy thereof.

The semiconductor chip 2500 may be a bare integrated circuit (IC) in which a separate bump or a separate wiring layer is not formed, but is not limited thereto, and may be a packaged type integrated circuit. The integrated circuit may be a processor chip, such as a central processor (CPU), a graphics processor (GPU), a field programmable gate array (FPGA), an application processor (AP), a digital signal processor, a cryptographic processor, a microprocessor, a microcontroller, or the like, but is not limited thereto, and may be a logic chip, such as an analog-to-digital converter, an application-specific IC (ASIC), or the like, or may be a memory chip including a volatile memory such as a dynamic RAM (DRAM), a static RAM (SRAM), or the like, and a non-volatile memory such as a phase change RAM (PRAM), a magnetic RAM (MRAM), a resistive RAM (RRAM), a flash memory, or the like.

The encapsulant 2400 may seal at least a portion of the semiconductor chip 2500 on an upper surface of the redistribution substrate 2100. The encapsulant 2400 may include, for example, a thermosetting resin, such as an epoxy resin, a thermoplastic resin such as polyimide, a prepreg in which an inorganic filler is impregnated thereinto, ABF, FR-4, BT, or an epoxy molding compound (EMC), but is not limited thereto.

The stiffener 130 may be disposed to at least partially surround the second package 2000 on a first surface S1 of a substrate 110. At least a portion of the stiffener 130 may be disposed along a first side LI in the first region R1 on which the second package 2000 is mounted. The stiffener 130 may have a tetragonal shape at least partially surrounding the second package 2000. A region defined by an internal side surface of the stiffener 130 may have a tetragonal shape, and may be larger than a region defined by the second package 2000.

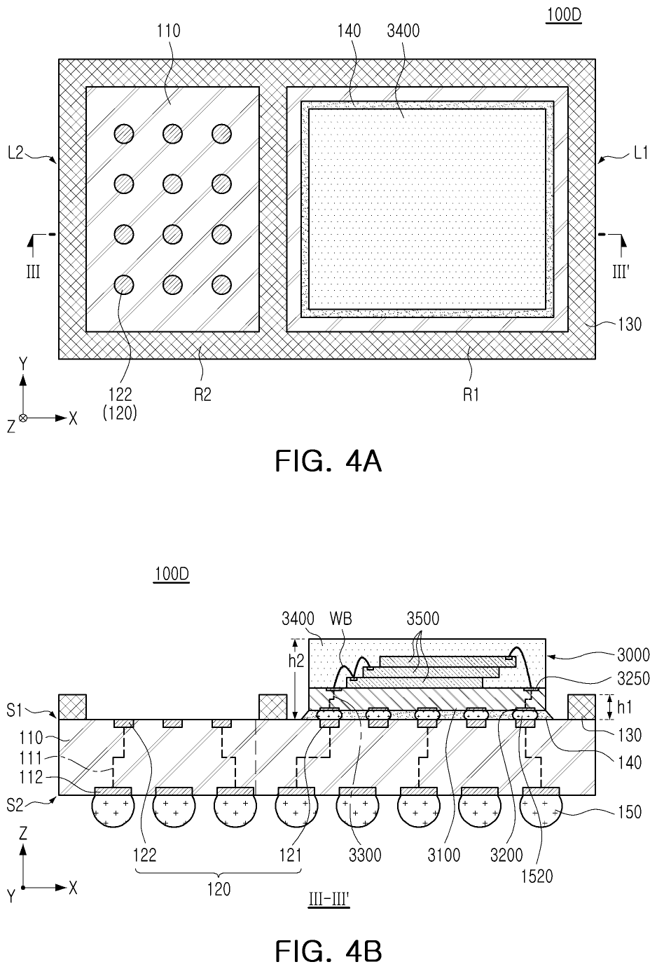

FIG. 4A is a top view illustrating an upper surface S1 of a substrate 110 of a semiconductor package 100D according to an embodiment, and FIG. 4B is a cross-sectional view of the semiconductor package 100D illustrated in FIG. 4A, taken along line III-III′.

Referring to FIGS. 4A and 4B, a semiconductor package 100D according to an embodiment may have the same or similar characteristics as illustrated with reference to FIGS. 1A to 3B, except that the semiconductor package 100D may include a semiconductor chip structure 3000, which may also be referred to as a third package 3000, and a stiffener 130 disposed to at least partially surround external edges of first and second regions R1 and R2.

A semiconductor package 100D according to an embodiment may include a third package 3000 mounted in a first region R1. The third package 3000 may include a redistribution substrate 3100, a plurality of semiconductor chips 3500, and an encapsulant 3400. The redistribution substrate 3100 may include a lower pad 3200 and an upper pad 3250 on lower and upper surfaces thereof, respectively, which may be electrically connected to an external source. Additionally, the redistribution substrate 3100 may include a redistribution circuit 3300 electrically connecting the lower pad 3200 and the upper pad 3250.

The plurality of semiconductor chips 3500 may be mounted on the redistribution substrate 3100 using a wire bonding method or a flip chip bonding method. For example, the plurality of semiconductor chips 3500 may be stacked in a direction, perpendicular to the redistribution substrate 3100, and may be electrically connected to the upper pad 3250 of the redistribution substrate 3100 by a bonding wire (WB). In an example embodiment, the plurality of semiconductor chips may include a logic chip.

The encapsulant 3400 may include the same or similar material as the encapsulant 2400 of the second package 2000. The third package 3000 may be physically and electrically connected to first connection pads 121 of a substrate 110 through conductive bumps 1520. The conductive bumps 1520 may be electrically connected to the redistribution circuit 3300 in the redistribution substrate 3100 through the lower pad 3200 of the redistribution substrate 3100.

The stiffener 130 may be disposed along the first region R1 and the second region R2 on a first surface S1 of the substrate 110. The stiffener 130 may be disposed to at least partially surround the third package 3000 mounted in the first region R1. The stiffener 130 may be disposed to be spaced apart from the third package 3000.

The stiffener 130 may be disposed along an external edge of the second region R2 of the substrate 110, and may be disposed to at least partially surround second connection pads 122 disposed in the second region R2. The stiffener 130 may include a portion disposed along a second side L2, and a portion extending from both corners of the second side L2. The portion extending from the both corners of the second side L2 may be connected to a portion extending from both corners of the first side L1. The stiffener 130 may be disposed along an external edge of the first surface S1 of the substrate 110.

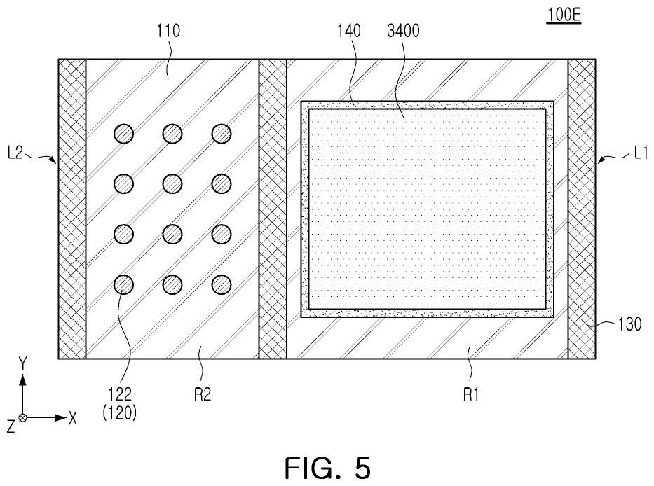

FIG. 5 is a top view illustrating an upper surface S1 of a substrate 110 of a semiconductor package 100E according to an embodiment.

Referring to FIG. 5, a semiconductor package 100E according to an embodiment may have the same or similar characteristics as illustrated with reference to FIGS. 1A to 4B, except that a stiffener 130 includes a plurality of portions parallel to a first side L1.

A semiconductor package 100E according to an embodiment may include a stiffener 130 in which several bars are attached to an upper surface S1 of a substrate 110. The stiffener 130 may include a portion disposed along a first side L1 and a portion disposed along a second side L2, and may include a portion extending parallel to the first and second sides L1 and L2. The portion extending parallel to the first and second sides L1 and L2 may be disposed along one end of a first region R1 adjacent to a second region R2, and may be spaced apart from a semiconductor chip structure 3000.

FIG. 6A is a top view illustrating an upper surface S1 of a substrate 110 of a semiconductor package 100F according to an embodiment, and FIG. 6B is a cross-sectional view of the semiconductor package 100F illustrated in FIG. 6A, taken along line IV-IV′.

Referring to FIGS. 6A and 6B, a semiconductor package 100F according to an embodiment may have the same or similar characteristics as illustrated with reference to FIGS. 1A to 5 except that first and second semiconductor chip structures 4100 and 4200 are mounted on a first surface S1 of a substrate 110, and a stiffener 130 is disposed to at least partially surround the first and second semiconductor chip structures 4100 and 4200.

In an embodiment, the first and second semiconductor chip structures 4100 and 4200 may be mounted on the first surface S1 of the substrate 110 of the semiconductor package 100F. Since the first and second semiconductor chip structures 4100 and 4200 have the same or similar characteristics as the above-described first package 1000 (see FIGS. 1A and 1B), detailed description of the first and second semiconductor chip structures 4100 and 4200 may be replaced with a description of the first package 1000. The first and second semiconductor chip structures 4100 and 4200 may be semiconductor chip structures of different sizes, but are not limited thereto. The first semiconductor chip structure 4100 may be mounted in a first region R1 of the substrate 110, and may be larger than the second semiconductor chip structure 4200 mounted in a second region R2. As semiconductor chip structures of different sizes are mounted on the substrate 110, the semiconductor package 100F according to an embodiment may have a structure in which the semiconductor chip structures are asymmetrically mounted.

The stiffener 130 may be disposed along peripheries of the first and second semiconductor chip structures 4100 and 4200. The stiffener 130 may be disposed along an external edge of the first surface S1 of the substrate 110, and at least a portion of the stiffener 130 may be disposed to extend between the first and second semiconductor chip structures 4100 and 4200. The stiffener 130 may be disposed along external edges of the first and second regions R1 and R2.

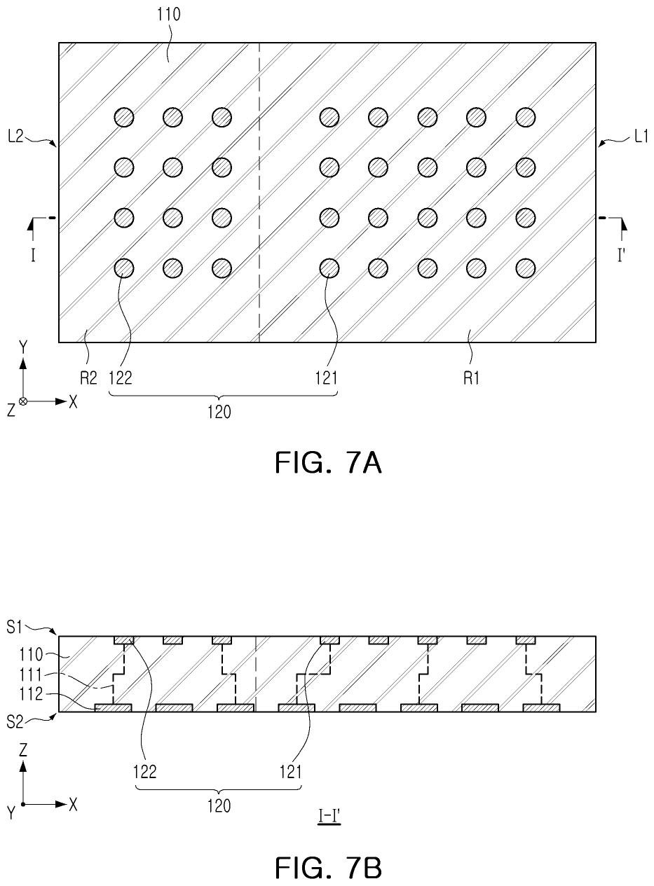

Hereinafter, a method of manufacturing the semiconductor package 100A illustrated in FIGS. 1A and 1B will be described with reference to FIGS. 7A to 9B.

FIGS. 7A, 8A, and 9A are top views of each main process illustrating a method for manufacturing a semiconductor package 100A according to an embodiment, and FIGS. 7B, 8B, and 9B are cross-sectional views of the top views of FIGS. 7A, 8A, and 9A, taken along line I-I′, respectively.

FIG. 7A is a top view illustrating an upper surface S1 of a substrate 110 during a process for manufacturing a semiconductor package 100A, and FIG. 7B is a cross-sectional view of the semiconductor package 100A illustrated in FIG. 7A, taken along line I-I′.

Referring to FIGS. 7A and 7B, a substrate 110 including an interconnection circuit layer 111, lower pads 112, and first and second connection pads 121 and 122 may be prepared. The substrate 110 may be a substrate formed by sawing a strip substrate in which a plurality of units are connected vertically and horizontally into a single unit, but is not limited thereto. In an embodiment, after processes to be described later are performed on the strip substrate to which a plurality of units are connected, the substrate 110 as a single unit may be formed along a sawing line in a final process.

The description described above with reference to FIGS. 1A and 1B may be applied to the interconnection circuit layer 111, the lower pads 112, and the first and second connection pads 121 and 122. Dotted lines illustrated in FIGS. 7A and 7B may be expressed for convenience only to distinguish a first region R1 on which a semiconductor chip structure 1000 is mounted and a second region R2 arranged side by side with the first region R1 in the X-axis direction. The first connection pads 121 may be disposed in the first region R1 adjacent to a first side L1, and the second connection pads 122 may be disposed in the second region R2 adjacent to a second side L2.

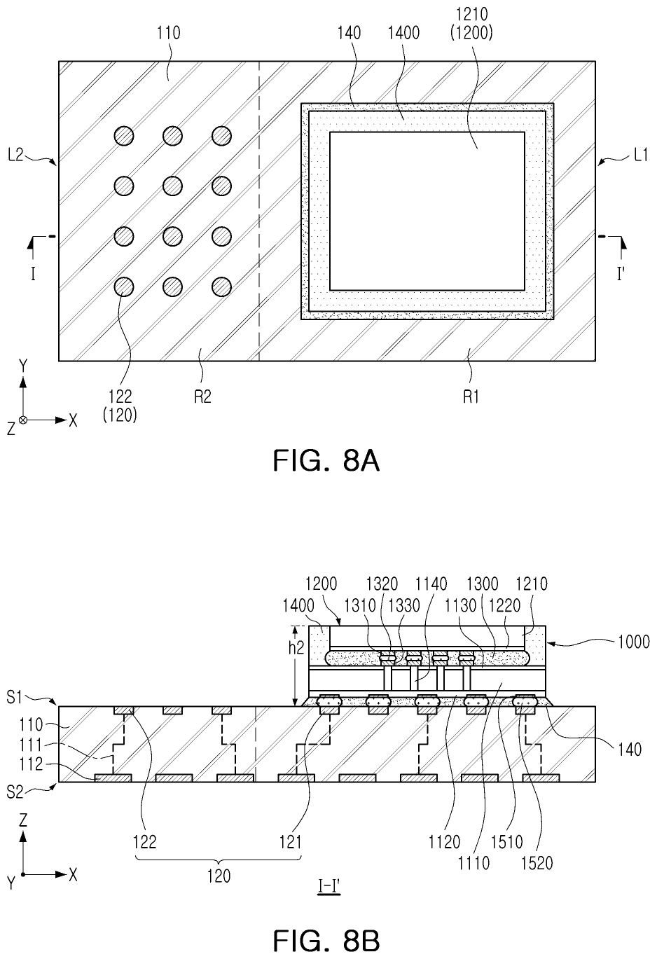

FIG. 8A is a top view illustrating an upper surface S1 of a substrate 110 during a process for manufacturing a semiconductor package 100A, and FIG. 8B is a cross-sectional view of the semiconductor package 100A illustrated in FIG. 8A, taken along line I-I′.

Referring to FIGS. 8A and 8B, a semiconductor chip structure 1000 may be mounted in a first region R1 of a substrate 110. Lower mounting pads 1510 disposed on a lowermost end of the semiconductor chip structure 1000 may be electrically connected to first connection pads 121 through conductive bumps 1520. An underfill 140 may at least partially surround and seal the conductive bumps 1520 and at least a portion of a lower portion of the semiconductor chip structure 1000. On a first surface S1 of the substrate 110, a region in which the underfill 140 is disposed may be larger than a region defined by the semiconductor chip structure 1000. The underfill 140 may be spaced apart from a region in which the stiffener 130 will be disposed in a later process. In the first region R1 of the substrate 110, the semiconductor chip structure 1000 connected to the first connection pads 121 is not limited to the first package 1000 of FIGS. 1A and 1B, and may include the packages of various embodiments described above in FIGS. 1 to 6B.

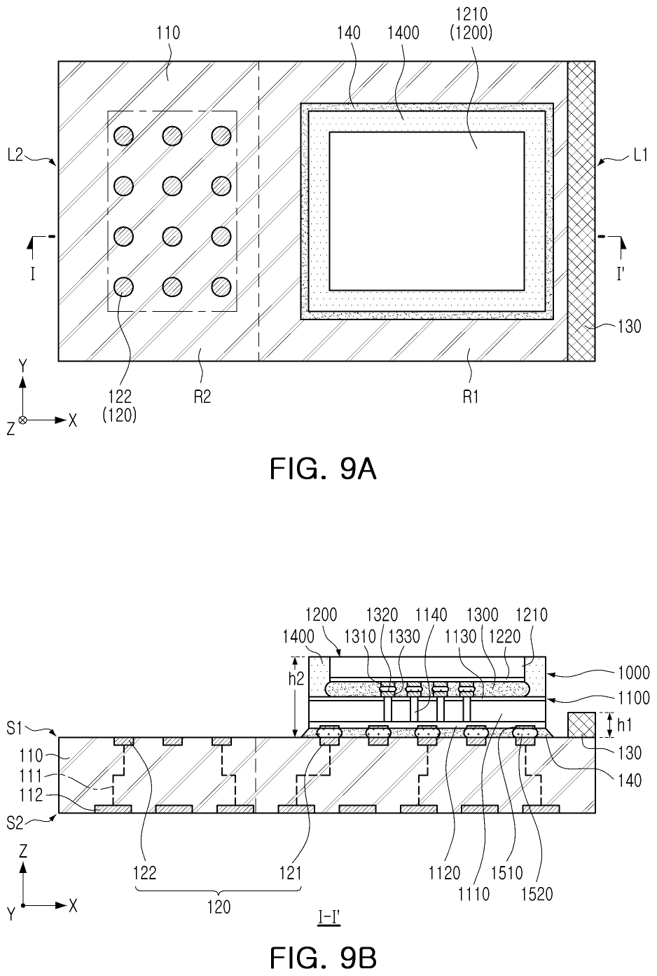

FIG. 9A is a top view illustrating an upper surface S1 of a substrate 110 during a process for manufacturing a semiconductor package 100A, and FIG. 9B is a cross-sectional view of the semiconductor package 100A illustrated in FIG. 9A, taken along line I-I′.

Referring to FIGS. 9A and 9B, a stiffener 130 may be disposed along an external edge of a first surface S1 of a substrate 110. The stiffener 130 may be disposed to cover or overlap at least two corner portions on one side on which a semiconductor chip structure 1000 is mounted. Specifically, the stiffener 130 may be disposed along a first side L1 in a first region R1 in which the semiconductor chip structure 1000 is mounted, and may extend to both corners of the first side L1. The stiffener 130 including a metal material and having a low coefficient of thermal expansion may be disposed in a corner portion in which a large amount of warpage occurs, thereby improving a warpage phenomenon of the package and improving the reliability of the device. A shape of the stiffener 130 is not limited to a shape of the stiffener 130 of FIGS. 1A and 1B, and may include the stiffener 130 of various embodiments described above with reference to FIGS. 2 to 6B. Depending on an embodiment, the stiffener 130 may be integrally connected or may include a plurality of portions spaced apart from each other.

Next, referring to FIGS. 1A and 1B together, external connection conductors 150 connected to lower pads 112 may be formed. The external connection conductors 150 may have a combination of a metal pillar and a solder ball, and may then be connected to an external device. As a result, the semiconductor package 100A of FIGS. 1A and 1B may be manufactured.

According to embodiments, a stiffener covering a corner portion of an upper surface of a substrate may be introduced to improve warpage of a semiconductor package and provide the semiconductor package with improved reliability.

While example embodiments have been illustrated and described above, it will be apparent to those skilled in the art that modifications and variations could be made without departing from the scope of the present disclosure as defined by the appended claims.

What is claimed is:

1. A semiconductor package comprising:
a substrate that comprises a first surface and a second surface that is opposite to the first surface, wherein the first surface comprises a first region and a second region, wherein the first region is adjacent to a first side of the substrate, wherein the second region is adjacent to a second side of the substrate, wherein the first side and the second side are opposite to each other, and wherein the substrate comprises a wiring circuit layer;
first connection pads in the first region of the substrate and second connection pads in the second region of the substrate, wherein the first connection pads and the second connection pads are electrically connected to the wiring circuit layer;
a semiconductor chip structure that is on the first region of the substrate and is connected to the first connection pads by conductive bumps;
a stiffener that extends along the first side and is in the first region of the substrate, wherein the stiffener extends to both corners of the first side;
an underfill on the first region of the substrate, wherein the underfill is spaced apart from the stiffener, wherein the underfill at least partially surrounds the conductive bumps, and wherein the underfill is between the semiconductor chip structure and the substrate; and
external connection conductors that are on the second surface of the substrate and electrically connected to the wiring circuit layer.

2. The semiconductor package of claim 1, wherein the stiffener further comprises a portion that extends from the both corners of the first side in a direction that is perpendicular to the first side.

3. The semiconductor package of claim 1, wherein the stiffener further comprises a first portion that extends along the second side and extends to both corners of the second side.

4. The semiconductor package of claim 3, wherein the stiffener further comprises a second portion that extends parallel to the first side and the second side.

5. The semiconductor package of claim 1, wherein the stiffener comprises a metal material.

6. The semiconductor package of claim 5, wherein the stiffener comprises at least one of stainless steel, copper (Cu), copper (Cu) alloy, nickel (Ni), or a nickel (Ni) alloy.

7. The semiconductor package of claim 1, wherein a height in which the stiffener extends from the first surface of the substrate is less than a height in which the semiconductor chip structure extends from the first surface of the substrate.

8. The semiconductor package of claim 1, wherein the semiconductor chip structure comprises a package that comprises a redistribution substrate, a redistribution layer, and a semiconductor chip.

9. The semiconductor package of claim 1, wherein the semiconductor chip structure comprises a plurality of semiconductor chips that are on the first surface of the substrate and that extend in a direction that is perpendicular to the first surface.

10. The semiconductor package of claim 1, wherein the semiconductor chip structure comprises at least one logic chip.

11. The semiconductor package of claim 10, further comprising a memory chip structure that is in the second region of the substrate and comprises a memory chip.

12. The semiconductor package of claim 11, wherein the stiffener extends along a perimeter of the semiconductor chip structure and a perimeter of the memory chip structure.

13. A semiconductor package comprising:
a substrate;
a semiconductor chip structure that is on the substrate and adjacent to one side surface of the substrate;
a stiffener that overlaps at least two corner portions of an upper surface of the substrate in a first direction, wherein the stiffener is spaced apart from the semiconductor chip structure, and wherein the stiffener comprises a tetragonal shape that at least partially surrounds the semiconductor chip structure; and
an underfill that overlaps at least a portion of a lower end of the semiconductor chip structure in the first direction.

14. The semiconductor package of claim 13, wherein a first region defined by an internal side surface of the stiffener is larger than a second region defined by the semiconductor chip structure.

15. The semiconductor package of claim 13, wherein the underfill is connected to at least a portion of the stiffener.

16. The semiconductor package of claim 13, wherein the stiffener extends along an external edge of the upper surface of the substrate.

17. A semiconductor package comprising:
a substrate;
a first semiconductor chip structure and a second semiconductor chip structure that are on an upper surface of the substrate and comprise different sizes;
a stiffener that is spaced apart from the first semiconductor chip structure and the second semiconductor chip structure and is on the upper surface of the substrate, wherein the stiffener extends along a perimeter of the first semiconductor chip structure and a perimeter of the second semiconductor chip structure; and
an underfill that seals at least a portion of the first semiconductor chip structure and at least a portion of the second semiconductor chip structure,
wherein the first semiconductor chip structure and the second semiconductor chip structure comprise a plurality of semiconductor chips that extend in a direction that is perpendicular to the upper surface of the substrate.

18. The semiconductor package of claim 17, wherein the plurality of semiconductor chips are a plurality of logic chips.

19. The semiconductor package of claim 18, wherein the plurality of logic chips comprise a lower logic chip that comprises a through-electrode and an upper logic chip that is electrically connected to the substrate through the through-electrode.

20. The semiconductor package of claim 17, wherein the stiffener is a metal film layer.
